(19) United States
(12) Patent Application Publication
(10) Pub. No.: US 2007/0184592 A1
(43) Pub. Date: Aug. 9, 2007

(54) Method for manufacturing semiconductor device

(76) Inventor: Kazuaki Nakajima, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/700,178

(22) Filed: Jan. 31, 2007

(30) Foreign Application Priority Data
Feb. 1, 2006 (JP) 2006-024888

(51) Int. Cl. H01L 21/84; H01L 21/00

(52) U.S. Cl. 438/166

(57) ABSTRACT

A gate insulating film is formed on a silicon substrate, a conductor film constituting a gate electrode is formed on the gate insulating film by a formation method using an organic material, and the silicon substrate, on which the conductor film is formed, is heated in a mixed atmosphere of steam which is an oxidizing atmosphere and hydrogen which is a reducing atmosphere with a partial pressure ratio of hydrogen to steam which is set such that carbon is oxidized and that a metal material constituting the conductor film is reduced.

### CROSS-REFERENCE TO RELATED APPLICATIONS

This application is based upon and claims the benefit of priority from the prior Japanese Patent Application No. 2006-024888 filed on Feb. 1, 2006; the entire contents of which are incorporated herein by reference.

### BACKGROUND OF THE INVENTION

1. Field of the Invention

The present invention relates to a method for manufacturing a semiconductor device and, more particularly, to a method for manufacturing a semiconductor device including a MOS transistor which uses a conductor film as a gate electrode.

2. Description of the Prior Art

Miniaturization of devices has conventionally been sought to achieve higher performance of a MOSFET (Metal Oxide Semiconductor Field Effect Transistor). Along with miniaturization of devices, the need to reduce power consumption has arisen. To reduce power consumption, the threshold value of a transistor needs to be kept low.

Polycrystal silicon is generally used in the gate electrode of a transistor. A low threshold value is achieved by doping polycrystal silicon portions serving as the gate electrodes of an N-type MOSFET and a P-type MOSFET with impurities to form n-type and p-type polycrystal silicon portions and setting the work function of the n-type polycrystal silicon portion near its conduction band and that of the p-type polycrystal silicon portion near its valence band.

However, even if a gate electrode made of polycrystal silicon is heavily doped with impurities such that the impurity concentration is of the order of 10²⁰ cm⁻³, which is the solubility limit of conductive impurities, a depletion layer is formed on the gate electrode side, and the gate capacitance decreases correspondingly. To cope with this, when forming a gate insulating film, its thickness needs to be reduced by about 0.5 nm in consideration of a decrease in gate capacitance corresponding to the depletion layer. However, since tunnel current through the gate insulating film causes an increase in gate leakage current, it is difficult to thin a gate insulating film under the current circumstances.

As away to avoid such a problem, an increase of the dielectric constant of a gate insulating film and utilization of a metal gate electrode are being considered. An increase of the dielectric constant of a gate insulating film means achieving the physical thickness of the gate insulating film and suppressing tunnel current by using a high-dielectric gate insulating film as the gate insulating film. Although there has recently been an increase in the development of materials for high-dielectric gate insulating films, discussions about these films are not at the stage for covering reliability yet, unlike conventional discussions about silicon oxide films. It will take some time before application of high-dielectric gate insulating films to actual devices.

The utilization of a metal gate electrode means preventing depletion in a gate electrode by switching the material for the gate electrode from polycrystal silicon to metal. If a metal gate electrode is adopted, a device is formed using a metal having a work function near 4.0 eV, which is within the conduction band of silicon, as the material for the gate electrode of an N-type MOSFET and a metal having a work function near 5.1 eV, which is within the valence band of silicon, as the material for the gate electrode of a P-type MOSFET, in order to keep the threshold value of a transistor low.

In these years, tungsten (W) having a work function of 5.0 eV has been considered promising as the material for the gate electrode of a P-type MOSFET. There is proposed a method for forming a tungsten film by chemical vapor deposition (to be referred to as CVD hereinafter) using W(CO)₆ gas as a source gas and forming a tungsten gate electrode (see, e.g., U.S. Pat. No. 5,789,312).

However, a large amount of carbon (C) may be contained in a tungsten film formed using W(CO)₆ gas by the method described in U.S. Pat. No. 5,789,312 or the like. Carbon contained in a tungsten film (to be referred to as residual carbon) diffuses in a gate insulating film due to heat applied to a semiconductor device during manufacture and precipitates near the interface with the gate insulating film to become a contributing factor in the generation of fixed charge. Fixed charge at the interface between a gate electrode and the gate insulating film causes a flat band voltage to vary in response to the change of the thickness of the gate insulating film. Accordingly, threshold values vary among a plurality of P-type MOSFETs mounted on the semiconductor device, and the quality of the semiconductor device deteriorates. If the design of a semiconductor device, more particularly the thickness of a gate insulating film, is changed along with miniaturization of devices, the threshold value of a P-type MOSFET changes accordingly. In order to obtain a desired threshold value, the design and manufacturing process of a gate electrode needs to be changed, and thus, the cost for developing products increases.

### SUMMARY OF THE INVENTION

A method for manufacturing a semiconductor device according to an embodiment of the present invention includes forming a gate insulating film on a semiconductor substrate, forming a conductor film constituting a gate electrode on the gate insulating film by a formation method using an organic material, and heating the semiconductor substrate, on which the conductor film is formed, in a mixed atmosphere of an oxidizing atmosphere and a reducing atmosphere with a partial pressure ratio of the reducing atmosphere to the oxidizing atmosphere which is set such that carbon is oxidized and that a metal material constituting the conductor film is reduced.

### BRIEF DESCRIPTION OF THE DRAWINGS

FIGS. 1A and 1B are section views for explaining the process of manufacturing a semiconductor device according to a first embodiment of the present invention;

FIG. 2 is a graph of C-V characteristics each showing the result of measuring the dependence of the electric capacity of a MOS capacitor on voltage;

FIG. 3 is a graph showing the relationships between flat band voltages obtained from C-V characteristics and oxide film thicknesses;

FIG. 4 is a graph showing the temperature dependence of a critical hydrogen-to-steam partial pressure ratio in a mixed atmosphere of a steam atmosphere and a hydrogen atmosphere;

FIGS. 5A, 5B, 5C, 5D, and 5E are section views for explaining the process of manufacturing a semiconductor device according to a second embodiment of the present invention;

FIGS. 6A, 6B, 6C, and 6D are section views for explaining the process of manufacturing the semiconductor device according to the second embodiment of the present invention;

FIGS. 7A, 7B, 7C, 7D, and 7E are section views for explaining the process of manufacturing a semiconductor device according to a third embodiment of the present invention; and

FIGS. 8A, 8B, and 8C are section views for explaining the process of manufacturing the semiconductor device according to the third embodiment of the present invention.

### DETAILED DESCRIPTION OF THE PREFERRED EMBODIMENTS

Embodiments of the present invention will be explained below with reference to the drawings.

### First Embodiment

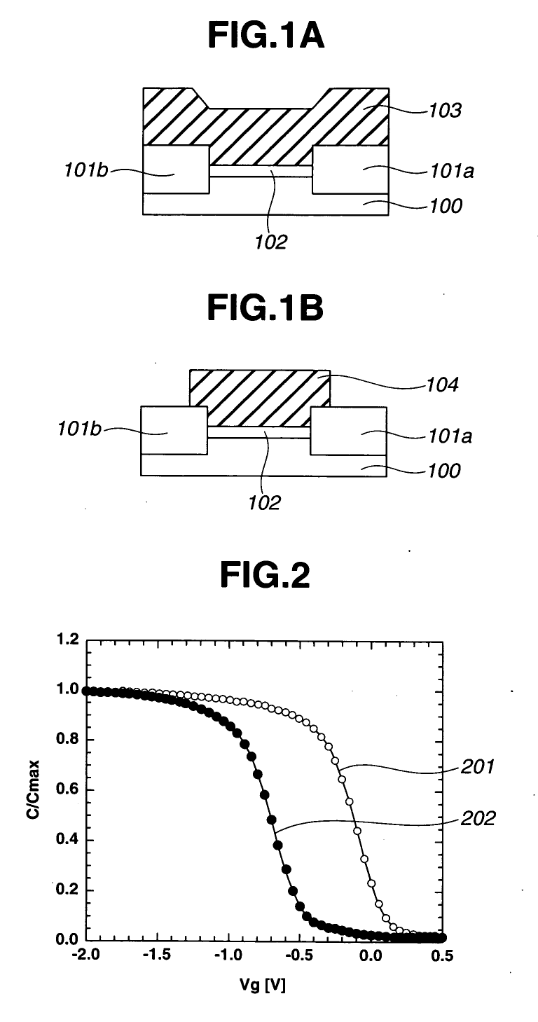

A method for manufacturing a semiconductor device according to a first embodiment of the present invention will first be explained with reference to FIGS. 1A and 1B. FIGS. 1A and 1B are section views for explaining the process of manufacturing the semiconductor device according to the first embodiment of the present invention. Note that this embodiment will explain a case where the method for manufacturing the semiconductor device of the present invention is applied to the process of manufacturing a P-type MOS capacitor constituting a gate portion of a P-type MOSFET.

As shown in FIG. 1A, element isolation insulating films 101a and 101b are formed in a region other than an element formation region on a silicon substrate 100 having a single-crystal structure using, e.g., the LOCOS technique. A thin gate insulating film 102 such as a silicon oxide film is formed on the surface of the silicon substrate 100 by, e.g., thermal oxidation. A tungsten film 103 having a work function of 5.0 eV is deposited on the gate insulating film 102 to a thickness of 100 nm by chemical vapor deposition (to be referred to as CVD hereinafter) using an organic material as a source.

On the tungsten film 103, a resist (not shown) is selectively formed only in a region where a gate electrode of a P-type MOS capacitor is to be formed. After the tungsten film 103 is anisotropically etched using the resist as a mask, ashing processing is performed to remove the resist. As shown in FIG. 1B, a gate electrode 104 having a predetermined gate width is formed.

Heat treatment is performed at a temperature of, e.g., about 800° C. for about 10 minutes in a mixed atmosphere of a reducing atmosphere of, e.g., hydrogen and an oxidizing atmosphere of, e.g., steam. At this time, the partial pressure ratio between hydrogen and steam is set to, e.g., 5:1. More specifically, the partial pressure ratio between the reducing atmosphere and the oxidizing atmosphere in heat treatment is set such that the tungsten film 103 constituting the gate electrode 104 is not oxidized and that carbon contained in the tungsten film 103 is oxidized. Note that the temperature and the partial pressure ratio between the reducing atmosphere and the oxidizing atmosphere at the time of heat treatment are appropriately set according to the type of a metal constituting the gate electrode 104. A method for deriving specific conditions to be set for heat treatment will be described later.

Finally, heat treatment is performed at a temperature of about 450° C. in, e.g., an atmosphere of dilute 10% hydrogen gas, thereby completing a MOS capacitor.

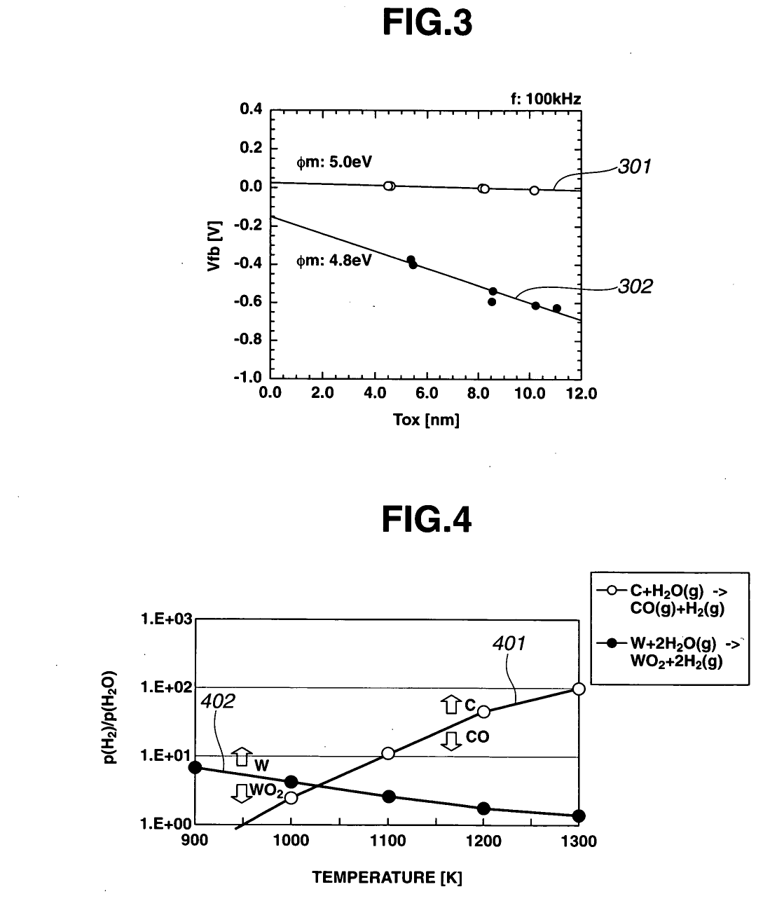

Prior to an explanation about the work function of the gate electrode 104 of the MOS capacitor formed in this manner, the work function of the gate electrode 104 of a MOS capacitor formed using a conventional manufacturing method will be explained. The work function of the gate electrode of a MOS capacitor formed using the conventional manufacturing method will be explained with reference to FIGS. 2 and 3.

FIG. 2 is a graph of C-V characteristics each showing the result of measuring the dependence of the electric capacity of a MOS capacitor on voltage. FIG. 3 is a graph showing the relationships between flat band voltages obtained from C-V characteristics and oxide film thicknesses. In FIG. 2, reference numeral 201 denotes a C-V curve of a MOS capacitor which is subjected not to heat treatment in a mixed atmosphere but to heat treatment in an atmosphere of dilute 10% hydrogen gas after the formation of the gate electrode 104. Reference numeral 202 in FIG. 2 denotes a C-V curve of a MOS capacitor which is subjected to heat treatment at a temperature of about 1,000° C. for about 30 seconds and then to heat treatment in an atmosphere of dilute 10% hydrogen gas, after the formation of the gate electrode 104.

Flat band voltages Vfb are obtained from the C-V curves 201 and 202 shown in FIG. 2. The flat band voltage Vfb obtained from the C-V curve 201 is +0.05 V while that obtained from the C-V curve 202 is −0.50 V. This shows that high-temperature heat treatment at 1,000° C. for 30 seconds causes the value of Vfb to shift by −0.55 V.

In order to obtain the work function of a gate electrode in a MOS capacitor having a C-V characteristic as indicated by the C-V curve 201 and the work function of a gate electrode in a MOS capacitor having a C-V characteristic as indicated by the C-V curve 202, a plurality of MOS capacitors whose gate insulating films 102 have different thicknesses were formed, Vfb was obtained for each of the MOS capacitors by acquiring a C-V characteristic as shown in FIG. 2, and the dependence of Vfb on gate insulating film thickness was evaluated (see FIG. 3).

In FIG. 3, a characteristic 301 indicates the dependence of Vfb on gate insulating film thickness in MOS capacitors which are subjected not to heat treatment in a mixed atmosphere but to heat treatment in an atmosphere of dilute 10% hydrogen gas after the formation of the gate electrodes 104. A characteristic 302 indicates the dependence of Vfb on gate insulating film thickness in MOS capacitors which are subjected to heat treatment at a temperature of about 1,000° C. for about 30 seconds and then to heat treatment in an atmosphere of dilute 10% hydrogen gas, after the formation of the gate electrodes 104.

As shown in FIG. 3, the characteristic 301 indicates that the work function of the gate electrode of each MOS capacitor formed using the conventional manufacturing method is 5.0 eV. The characteristic 302 indicates that the work function of the gate electrode of each MOS capacitor which is formed using the conventional manufacturing method and then subjected to high-temperature heat treatment at 1,000° C. for 30 seconds is 4.8 eV. That is, the work functions of the two types of gate electrodes seem to have almost the same values.

In each MOS capacitor which is not subjected to high-temperature heat treatment at 1,000° C. for 30 seconds, the value of Vfb is almost the same regardless of gate insulating film thickness, i.e., the slope is almost zero, as indicated by the characteristic 301. In contrast, in each MOS capacitor which is subjected to high-temperature heat treatment at 1,000° C. for 30 seconds, the slope is steep, as indicated by the characteristic 302. The value of Vfb becomes lower with an increase in gate insulating film thickness. Each of the work functions of the gate electrodes obtained above is based on the value of the flat band voltage when the interface state at the interface between the gate insulating film and a silicon substrate remains constant, and the thickness of the gate electrode film is zero. Also, each work function is calculated on the premise that the amount of fixed charge at the interface between the gate electrode and the gate insulating film is zero. If gate electrodes are formed on the same gate insulating film, and the amount of fixed charge at the interface between each gate electrode and the gate insulating film is zero, the characteristics of the dependence of Vfb on gate insulating film thickness for the gate electrodes have almost the same slope.

The slope of the characteristic 302 of the MOS capacitors which are subjected to high-temperature heat treatment at 1,000° C. for 30 seconds is much steeper than that of the characteristic 301 of the MOS capacitors which are not subjected to high-temperature heat treatment at 1,000° C. for 30 seconds. From this, it is conceivable that each MOS capacitor which is subjected to high-temperature heat treatment at 1,000° C. for 30 seconds contains a large amount of fixed charge at the interface between the gate electrode and the gate insulating film.

Accordingly, in each MOS capacitor which is subjected to high-temperature heat treatment at 1,000° C. for 30 seconds, the distribution of constituent elements in a depth direction from the gate electrode toward the silicon substrate was measured using secondary ion mass spectrometry. The measurement result shows that carbon (C) is diffused from the gate electrode toward the gate insulating film. In this embodiment, since the gate electrode 104 is formed by processing the tungsten film 103, which is formed by CVD using an organic source, about several percent of carbon remains in the gate electrode 104. It is conceivable that the residual carbon diffused in the gate insulating film 102 by being subjected to high-temperature heat treatment at 1,000° C. for 30 seconds and functioned as fixed charge at the interface between the gate electrode 104 and the gate insulating film 102. Accordingly, the work function (=4.8 eV) calculated from the characteristic 302 in FIG. 3 is a value in a state containing a large amount of fixed charge, and thus, is not the true work function.

In other words, it is conceivable that since each MOS capacitor formed using the conventional manufacturing method contains a large amount of residual carbon in the gate electrode, high-temperature heat treatment for forming a source/drain diffusion layer of a MOSFET causes the residual carbon to diffuse in the gate insulating film and function as fixed charge, and Vfb shifts in a minus direction. Since the shift amount of Vfb changes according to the thickness of each gate insulating film, variations in thickness among gate insulating films due to process variations or the like cause variations in Vfb among a plurality of MOSFETs mounted on a semiconductor device. This leads to a deterioration in the quality of the semiconductor device.

Removal of residual carbon contained in the tungsten film 103 makes it possible to prevent generation of fixed charge at the interface between the gate electrode 104 and the gate insulating film 102 and cause Vfb to have a stable value. The most effective means of removing residual carbon is thermal oxidation of carbon. In this case, if the tungsten film 103 constituting the gate electrode 104 is oxidized together with carbon, the function of the gate electrode 104 is impaired. Accordingly, it is necessary to perform heat treatment under conditions that allow carbon to be oxidized but do not allow tungsten to be oxidized. Conditions for heat treatment that allow carbon to be oxidized but do not allow tungsten to be oxidized will be derived below.
C+H₂O=CO+H₂ (1)
W+2H₂O=WO₂+2H₂ (2)

Formula (1) is a reaction formula associated with oxidation and reduction of carbon. Formula (2) is a reaction formula associated with oxidation and reduction of tungsten. In a steam atmosphere which is an oxidizing atmosphere, carbon and tungsten are oxidized, reactions in Formulae (1) and (2) proceed from the left-hand side to right-hand side, and oxides (carbon monoxide and tungsten dioxide) are generated. On the other hand, in a hydrogen atmosphere which is a reducing atmosphere, carbon monoxide and tungsten dioxide are reduced, the reactions in Formulae (1) and (2) proceed from the right-hand side to left-hand side, and carbon and tungsten are generated.

Which one of oxidation and reduction reactions occurs, i.e., in which direction the reaction in each of Formulae (1) and (2) proceeds depends on whether a change (ΔG) in Gibbs free energy in each system has a negative value. For example, assume that carbon is subjected to heat treatment in a steam atmosphere as in Formula (1). Within a temperature range of not less than 947 K, ΔG becomes less than 0, the reaction in Formula (1) proceeds from the left-hand side to right-hand side, and carbon is oxidized. On the other hand, within a temperature range of less than 947 K, ΔG becomes more than 0, the reaction in Formula (1) proceeds from the right-hand side to left-hand side, and carbon monoxide is reduced to generate carbon.

If heat treatment is performed in a mixed atmosphere of a steam atmosphere which is an oxidizing atmosphere and a hydrogen atmosphere which is a reducing atmosphere, ΔG is governed by the partial pressure ratio between the atmospheres, as indicated by Formula (3):
ΔG∝ln (pH₂/pH₂O) (3)

In Formula (3), pH₂ and pH₂O represent the pressure of hydrogen and that of steam, respectively. In heat treatment in a mixed atmosphere, a point where the sign of ΔG changes, i.e., a critical partial pressure ratio which forms the border between oxidation and reduction reactions depends on temperature, as shown in FIG. 4. FIG. 4 is a graph showing the temperature dependence of a critical hydrogen-to-steam partial pressure ratio in a mixed atmosphere of a steam atmosphere and a hydrogen atmosphere. In FIG. 4, a characteristic 401 indicates the temperature dependence of a critical hydrogen-to-steam partial pressure ratio for carbon. A characteristic 402 indicates the temperature dependence of a critical hydrogen-to-steam partial pressure ratio for tungsten. In a region below the characteristic 401 (or 402), i.e., within a range with a low partial pressure ratio, an oxidation reaction which is a reaction from the left-hand side to right-hand side of Formula (1) (or (2)) proceeds. On the other hand, in a region above the characteristic 401 (or 402), i.e., within a range with a high partial pressure ratio, a reduction reaction which is a reaction from the right-hand side to left-hand side of Formula (1) (or (2)) occurs.

As shown in FIG. 4, the characteristic 401 of the temperature dependence of the critical hydrogen-to-steam partial pressure ratio for carbon and the characteristic 402 of the temperature dependence of the critical hydrogen-to-steam partial pressure ratio for tungsten cross each other at a temperature near 1,030 K. Heat treatment at a temperature higher than the temperature where the characteristics 401 and 402 cross each other with a partial pressure ratio between steam and hydrogen which is set to be included in a region below the characteristic 401 and above the characteristic 402, makes it possible to oxidize only carbon without oxidizing tungsten. If carbon is subjected to heat treatment in an oxidizing atmosphere, carbon dioxide may be generated instead of carbon monoxide. However, at a temperature not less than 1,000 K, a formation energy ΔG_{CO} of carbon monoxide per oxygen atom is lower than a formation energy ΔG_{CO2} of carbon dioxide per oxygen atom, and carbon monoxide is thermodynamically more stable. Accordingly, to derive conditions. for oxidation in a mixed atmosphere, it suffices to take into consideration only cases where carbon monoxide is generated.

For example, if heat treatment is performed under the conditions of temperature: about 800° C. (=about 1,073 K), the ratio between hydrogen and steam: 5:1, and heating time: 10 minutes when the MOS capacitor shown in FIG. 1B is heated in the mixed atmosphere in the process of manufacturing a MOS capacitor explained with reference to FIGS. 1A and 1B, the concentration of carbon in the gate electrode 104 can be reduced to about 0.01% without oxidizing the gate electrode 104 formed from the tungsten film 103.

The C-V characteristic of the MOS capacitor formed using the manufacturing method of this embodiment explained with reference to FIGS. 1A and 1B is the same as that (the C-V curve 201 in FIG. 2) of the MOS capacitor formed using the conventional manufacturing method. Even if the MOS capacitor formed using the manufacturing method of this embodiment is further subjected to high-temperature heat treatment at 1,000° C. for 3 seconds, the C-V characteristic does not change. The work function of the gate electrode 104 of the thus formed MOS capacitor is 5.0 eV, and a work function near 5.1 eV within the valence band of silicon which is required of a P-type MOSFET can be implemented.

As described above, according to this embodiment, when manufacturing a P-type MOS capacitor constituting a gate portion of a P-type MOSFET, only residual carbon in the gate electrode 104 can be oxidized and removed by processing the tungsten film 103 to form the gate electrode and then performing heat treatment under conditions as described above (in a mixed atmosphere of an oxidizing atmosphere and a reducing atmosphere with a combination of a temperature and a partial pressure ratio which allows carbon to be oxidized but does not allow tungsten to be oxidized). Even if high-temperature heat treatment is further performed to form a source/drain of the MOSFET, it is possible to prevent residual carbon from diffusing from the gate electrode 104 into the gate insulating film 102 and suppress generation of fixed charge caused by the diffusion. Accordingly, even if the thickness of the gate insulating film 102 changes, the flat band voltage can remain constant, the quality of a semiconductor device can be improved.

Note that although in this embodiment, tungsten is used as the material for the gate electrodes 104, any other material may be used as far as it is an element (one belonging to Group VIa) homologous to tungsten in a periodic table of elements. For example, molybdenum (Mo) or an alloy of molybdenum may be used.

Each gate insulating film 102 need not be a silicon oxide film formed by thermal oxidation and may be an insulating film, having a higher dielectric constant than a silicon oxide film. For example, an oxide of hafnium (Hf), zirconium (Zr), titanium (Ti), tantalum (Ta), aluminum (Al), strontium (Sr), yttrium (Y), lanthanum (La), or the like or an oxide of a compound of any of the elements and silicon, such as ZrSiₓO_{y}, may be used. Alternatively, a film formed by stacking layers of these oxides may be used.

### Second Embodiment

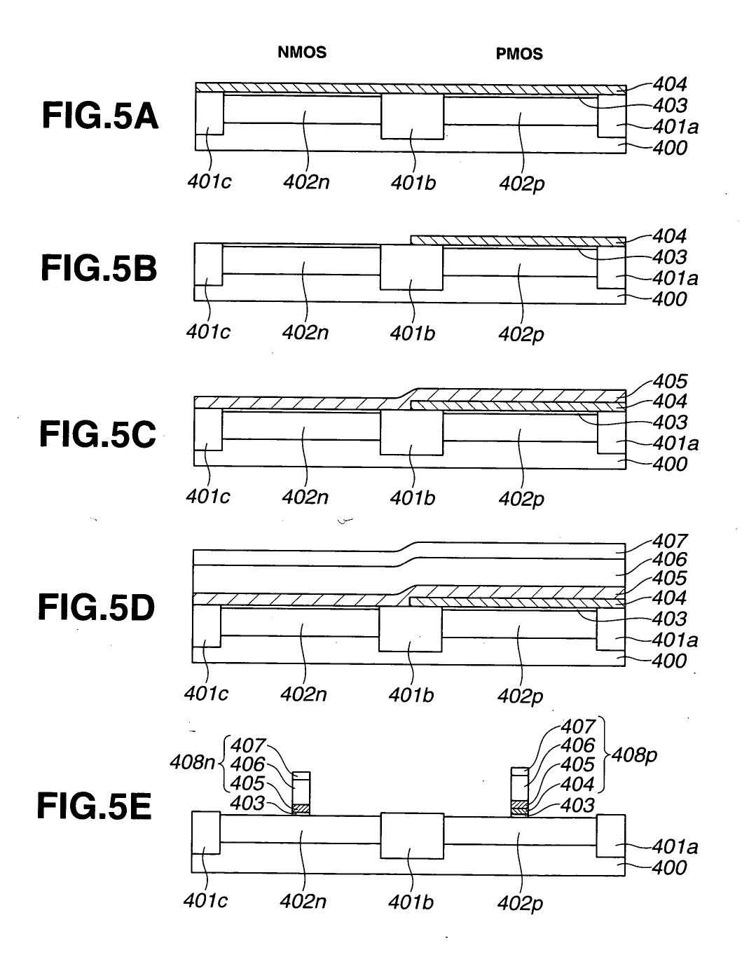

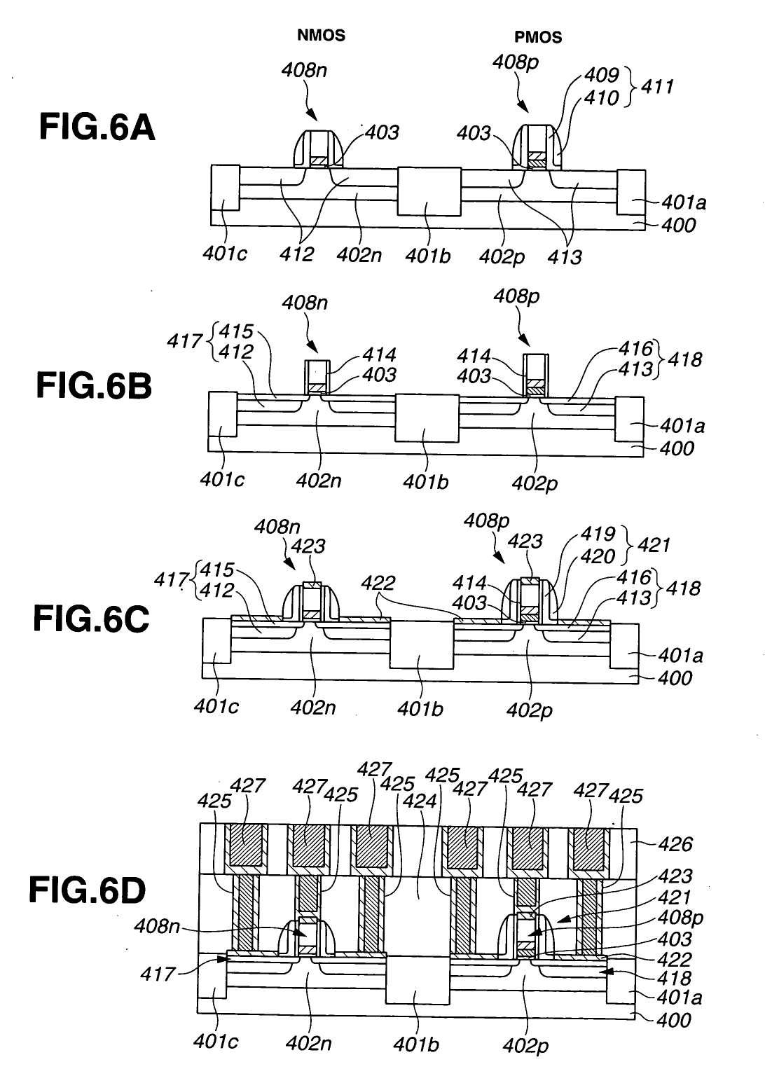

A method for manufacturing a semiconductor device according to a second embodiment of the present invention will be explained with reference to FIGS. 5A to 5E and FIG. 6A to 6D. FIGS. 5A to 5E and FIGS. 6 A to 6D are section views for explaining the process of manufacturing a semiconductor device according to the second embodiment of the present invention. Note that this embodiment will explain a case where the method for manufacturing a semiconductor device of the present invention is applied to the process of manufacturing a CMOS-type semiconductor device having an N-type MOSFET and a P-type MOSFET.

As shown in FIG. 5A, element isolation insulating films 401a to 401c are formed in a region, other than element formation regions on a silicon substrate 400 using STI technology or the like. A p-well 402p and an n-well 402n are formed in regions on the silicon substrate 400 where an N-type MOSFET and a P-type MOSFET are to be formed. Gate insulating films 403 containing hafnium are formed on the surface of the silicon substrate 400 by CVD using an organic material as a source.

A tungsten film 404 having a work function of 4.9 eV is deposited on the gate insulating films 403 to a thickness of 10 nm by CVD using the organic material as the source. Heat treatment is performed at a temperature of, e.g., about 850° C. for about 30 minutes in a mixed atmosphere of a reducing atmosphere of, e.g., hydrogen and an oxidizing atmosphere of, e.g., steam. At this time, the flow ratio between gases (hydrogen (H₂): steam (H₂O): nitrogen (N₂)) supplied to an oxidation furnace where heat treatment is performed is set to, e.g., 2:0.4:3.5 (slm). The conditions are ones that allow carbon to be oxidized but do not allow tungsten to be oxidized. Heat treatment under these conditions makes it possible to selectively oxidize and remove only residual carbon contained in the tungsten film 404, which is a surface layer. Note that the temperature for selective oxidation and the partial pressure ratio between the oxidizing atmosphere and the reducing atmosphere are not limited to the above-described ones and that any conditions may be used as far as they are ones that allow carbon to be oxidized but do not allow tungsten to be oxidized.

As shown in FIG. 5B, a part of the tungsten film 404 in the region where the N-type MOSFET is to be formed is selectively removed (etched) using, e.g., a hydrogen peroxide solution. As shown in FIG. 5C, a tungsten silicon nitride (WSiN) film 405 having a work function of 4.2 eV is deposited on the entire surface to a thickness of 10 nm by, e.g., CVD.

As shown in FIG. 5D, a polycrystal silicon film 406 is deposited on the entire surface to a thickness of 10 nm by, e.g., CVD, and then a resist (not shown) is selectively formed in the region where the P-type MOSFET is to be formed. Ions of, e.g., As⁺ are implanted into a part of the polycrystal silicon film 406 formed in the region where the N-type MOSFET is to be formed, using the resist as a mask. After ashing processing is performed to remove the resist, a resist (not shown) is selectively formed only in the region where the N-type MOSFET is to be formed. Ions of, e.g., B⁺ are implanted into a part of the polycrystal silicon film 406 formed in the region where the P-type MOSFET is to be formed, using the resist as a mask. After ashing processing is performed to remove the resist, a silicon nitride film 407 is deposited on the entire surface to a thickness of 40 nm by, e.g., CVD.

As shown in FIG. 5E, resists (not shown) are selectively formed only in regions where gate electrodes of the N-type MOSFET and P-type MOSFET are to be formed. The silicon nitride film 407, polycrystal silicon film 406, tungsten siliconnitride (WSiN) film 405, and tungsten film 404 are anisotropically etched using the resists as a mask. After that, ashing processing is performed to remove the resists. With the etching processing, gate electrodes 408n and 408p having a width of, e.g., 30 nm are formed.

A silicon nitride film 409 and a silicon oxide film 410 are deposited on the entire surface in this order by, e.g., CVD, and then overall etchback is performed. With this process, gate sidewall insulating films 411, each of which is composed of the silicon nitride film 409 and silicon oxide film 410, are formed on the sidewalls of the gate electrodes 408n and 408p, as shown in FIG. 6A.

A resist (not shown) is selectively formed on the surface in the region where the P-type MOSFET is to be formed, and ions of, e.g., P⁺ are implanted into the region of the silicon substrate 400, where the N-type MOSFET is to be formed, using the resist, gate electrode 408n, and gate sidewall insulating films 411 as a mask. After ashing processing is performed to remove the resist, a resist (not shown) is selectively formed in the region on the surface, where the N-type MOSFET is to be formed, and ions of, e.g., B⁺ are implanted into the region of the silicon substrate 400, where the P-type MOSFET is to be formed, using the resist, gate electrode 408p, and gate sidewall insulating films 411 as a mask. After ashing processing is performed to remove the resist, heat treatment is performed at a temperature of, e.g., 1,030° C. for 5 seconds, thereby forming deep diffusion layers 412 and 413.

As shown in FIG. 6B, the silicon nitride films 409 and silicon oxide films 410 forming the gate sidewall insulating films 411 are removed by, e.g., wet etching. At this time, the silicon nitride films 407, which are formed as the outermost layers of the gate electrodes 408n and 408p, are also removed. A silicon nitride film 414 is deposited on the entire surface by, e.g., CVD, and then overall etchback is performed. With this process, a structure is formed in which the sidewalls of the gate electrodes 408n and 408p are surrounded by the silicon nitride films 414.

A resist (not shown) is selectively formed in the region on the surface, where the P-type MOSFET is to be formed, and ions of, e.g., As⁺ are implanted into the region of the silicon substrate 400, where the N-type MOSFET is to be formed, using the resist, the gate electrode 408n, and silicon nitride films 414 as a mask. After ashing processing is performed to remove the resist, a resist (not shown) is selectively formed in the region on the surface, where the N-type MOSFET is to be formed, and ions of, e.g., B⁺ are implanted into the region of the silicon substrate 400, where the P-type MOSFET is to be formed, using the resist, gate electrode 408p, and silicon nitride films 414 as a mask. After ashing processing is performed to remove the resist, heat treatment is performed at a temperature of, e.g., 800° C. for 5 seconds, thereby forming shallow diffusion layers 415 and 416.

In the above-described manner, source/drain diffusion layers 417 and 418 which are composed of the deep diffusion layer 412 and shallow diffusion layer 415 and the deep diffusion layer 413 and shallow diffusion layer 416, respectively, are formed on the two sides of the gate electrodes 408n and 408p in the silicon substrate 400. Note that in this embodiment, since the deep diffusion layers 412 and 413 are formed prior to the formation of the shallow diffusion layers 415 and 416, unnecessary high heat (heat treatment performed when forming the deep diffusion layers 412 and 413) can be prevented from being applied to the shallow diffusion layers 415 and 416, and elongation in a depth direction of the shallow diffusion layers 415 and 416 can be suppressed.

A silicon nitride film 419 and a silicon oxide film 420 are deposited on the entire surface in this order by, e.g., CVD, and then overall etchback is performed. With this process, gate sidewall insulating films 421, each of which is composed of the silicon nitride film 419 and silicon oxide film 420, are formed to surround the silicon nitride films 414 formed on the sidewalls of the gate electrodes 408n and 408p, as shown in FIG. 6C.

After, e.g., a nickel film (not shown) is deposited on the entire surface to a thickness of about 10 nm, heat treatment is performed at a temperature of 350° C. for 30 seconds, thereby causing a chemical reaction between the nickel film and the silicon substrate 400. A part of the nickel film which has not reacted with the silicon substrate 400 is selectively removed by, e.g., wet etching using a mixture of sulfuric acid and a hydrogen peroxide solution, and then heat treatment is performed at a temperature of 500° C. for about 30 seconds. With this process, nickel silicide layers 422 and 423 are formed in a self-aligned manner on the surfaces of the source/drain diffusion layers 417 and 418 and on the surface of the polycrystal silicon films 406 serving as the outermost layers of the gate electrodes 408n and 408p. Note that although in this embodiment, each nickel silicide layer 423 is formed on only a part of the surface of the corresponding polycrystal silicon film 406, the entire polycrystal silicon film 406 may be transformed to the nickel silicide layer 423.

As shown in FIG. 6D, a first interlayer insulating film 424 is deposited on the entire surface by, e.g., CVD, and the surface is planarized by chemical mechanical polishing (to be referred to as CMP hereinafter). Parts of the first interlayer insulating film 424 over the upper surfaces of the nickel silicide layers 422 formed on the source/drain diffusion layers 417 and 418 and parts of the first interlayer insulating film 424 over the upper surfaces of the nickel silicide layers 423 formed on the gate electrodes 408n and 408p are removed by anisotropic etching, thereby forming a contact pattern. That is, the first interlayer insulating film 424 is anisotropically etched such that the nickel silicide layers 422 formed on the source/drain diffusion layers 417 and 418 and the nickel silicide layers 423 formed on the gate electrodes 408n and 408p are exposed at the bottom of the contact pattern.

Titanium (Ti), titanium nitride (TiN), and tungsten (W) are deposited in the contact pattern in this order by, e.g., sputtering. The surface of the first-interlayer insulating film 424 is planarized by CMP, and the contact pattern is formed to have contact plugs 425 buried therein. A second interlayer insulating film 426 is then deposited on the entire surface by, e.g., CVD, and the surface is planarized by CMP.

The second interlayer insulating film 426 over the upper surfaces of the contact plugs 425 is removed by anisotropic etching, thereby forming a contact pattern. Tantalum nitride (TaN) and copper (Cu) are deposited in the contact pattern in this order by, e.g., sputtering. Finally, the surface of the second interlayer insulating film 426 is planarized by CMP, and wiring layers 427 which are electrically connected to the source/drain diffusion layers 417 and 418 or the gate electrodes 408n and 408p through the contact plugs 425 are formed. In this manner, a CMOS-type semiconductor device having the N-type MOSFET and P-type MOSFET is completed.

In the semiconductor device manufactured in the above-described manner, each of the gate electrodes 408n and 408p of the N-type MOSFET and P-type MOSFET has a structure formed by stacking a plurality of different films. The threshold value of each transistor is governed by the work function of the metal film in contact with the corresponding gate insulating film 403. In the semiconductor device, the tungsten silicon nitride (WSIN) film 405 having the work function of 4.2 eV is in contact with the gate insulating film 403 in the N-type MOSFET while the tungsten film 404 having the work function of 4.9 eV is in contact with the gate insulating film 403 in the P-type MOSFET. This means that the use of the manufacturing method of this embodiment makes it possible to manufacture the CMOS-type semiconductor device including the N-type MOSFET having the gate electrode 408n, whose work function is 4.2 eV, and the P-type MOSFET having the gate electrode 408p, whose work function is 4.9 eV.

As described above, in this embodiment, the tungsten film 404, which governs the threshold value of the gate electrode 408p of the P-type MOSFET, is subjected to selective oxidation processing under conditions that allow carbon to be oxidized but do not allow tungsten to be oxidized. Accordingly, even if the thickness of each gate insulating film 403 changes, the flat band voltage can remain constant, the quality of the semiconductor device can be improved, and the cost for developing products can be suppressed.

Note that although in this embodiment, tungsten silicon nitride (WSIN) is used as the material for the gate electrode 408n, and tungsten is used as that for the gate electrode 408p, a tungsten silicon (WSi) portion having a nitride layer formed on its surface may be used as the material for the gate electrode 408n. Alternatively, a combination of carbides of tungsten, such as tungsten silicon carbide (WSiC) and tungsten carbide (WC), or a combination of borides of tungsten, such as tungsten silicon boride (WSiB) and tungstenboride (WB), maybe used as the materials for the gate electrode 408n and gate electrode 408p.

Although in this embodiment, electrode materials which are mainly composed of tungsten are used as the materials for the gate electrodes 408n and 408p, any other material may be used as far as it is an element (one belonging to Group VIa) homologous to tungsten in a periodic table of elements. For example, molybdenum (Mo) or an alloy of molybdenum may be used. As the material for the gate electrode 408n of the N-type MOSFET, an electrode material which is mainly composed of an element belonging to Group IVa in the periodic table of elements, such as titanium (Ti), zirconium (Zr), and hafnium (Hf), or an element belonging to Group Va in the periodic table of elements, such as vanadium (V), niobium (Nb), and tantalum (Ta), may be used.

Each gate insulating film 403 need not be an oxide film containing hafnium. For example, an oxide of zirconium (Zr), titanium (Ti), tantalum (Ta), aluminum (Al), strontium (Sr), yttrium (Y), lanthanum (La), or the like or an oxide of a compound of any of the elements and silicon, such as ZrSiₓO_{y}, may be used. Alternatively, a film formed by stacking layers of these oxides may be used.

### Third Embodiment

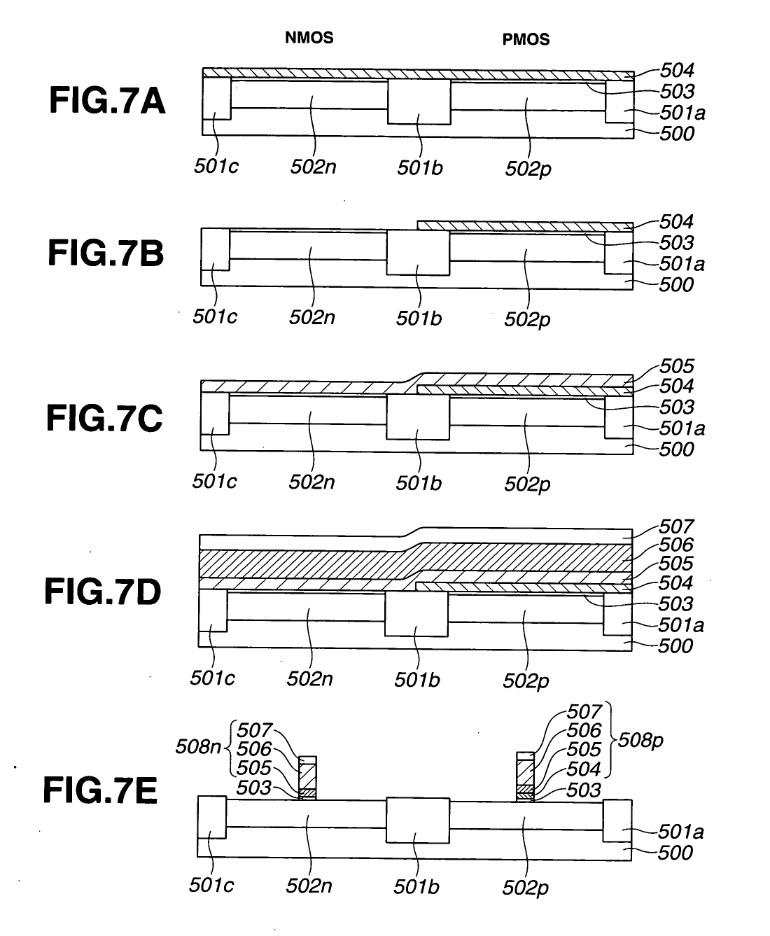

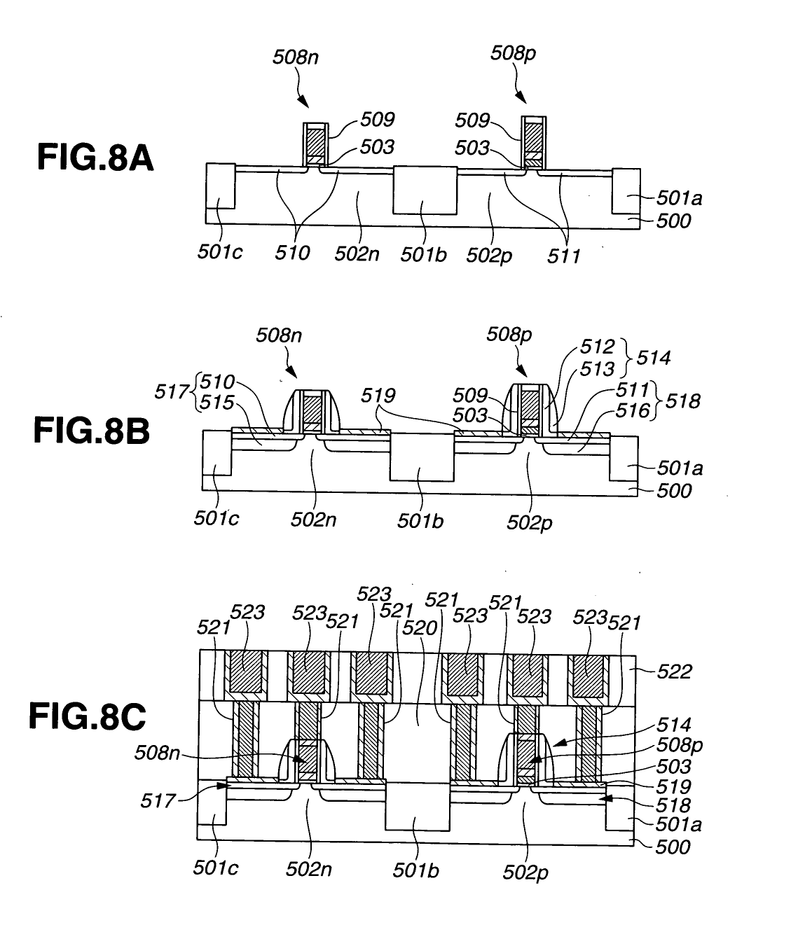

A method for manufacturing a semiconductor device according to a third embodiment of the present invention will be explained with reference to FIGS. 7A to 7E and FIGS. 8A to 8C. FIGS. 7A to 7E and FIGS. 8A to 8C are section views for explaining the process of manufacturing a semiconductor device according to the third embodiment of the present invention. Note that this embodiment will explain a case where the method for manufacturing a semiconductor device of the present invention is applied to the process of manufacturing a CMOS-type semiconductor device having an N-type MOSFET and a P-type MOSFET, similarly to the second embodiment.

This embodiment is different from the second embodiment in the structure of layers constituting the gate electrodes of the N-type MOSFET and P-type MOSFET and a method for forming a source/drain diffusion layer.

As shown in FIG. 7A, element isolation insulating films 501a to 501c are formed in a region, other than element formation regions on a silicon substrate 500 using STI technology or the like. A p-well 502p and an n-well 502n are formed in regions of the silicon substrate 500, where an N-type MOSFET and a P-type MOSFET are to be formed. A specific method for forming the element isolation insulating films 501a to 501c and p-well 502p and n-well 502n in this embodiment is the same as that in the second embodiment explained with reference to FIG. 5A.

Gate insulating films 503 containing hafnium are formed on the surface of the silicon substrate 500 by CVD using an organic material as a source. A molybdenum nitride (MoN) film 504 having a work function of 5.0 eV is deposited on the gate insulating films 503 to a thickness of 10 nm by CVD using the organic material as the source.

Heat treatment is performed at a temperature of, e.g., 850° C. for about 30 minutes in a mixed atmosphere of a reducing atmosphere of, e.g., hydrogen and an oxidizing atmosphere of, e.g., steam. At this time, the flow ratio between gases (hydrogen (H₂): steam (H₂O): nitrogen (N₂)) supplied to an oxidation furnace where heat treatment is performed is set to, e.g., 2:0.4:3.5 (slm).

An oxidation-reduction reaction of molybdenum can be represented by the following reaction formula:
Mo+2H₂O=MoO₂+2H₂ (4)

When a critical partial pressure ratio which forms the border between oxidation and reduction reactions with respect to heating temperature for molybdenum is derived using Formula (4) and Gibbs free energy in the same manner as in the first embodiment, a characteristic similar to the characteristic of the critical hydrogen-to-steam partial pressure ratio for tungsten shown in FIG. 4 is obtained.

The conditions for the heat treatment are ones that allow carbon to be oxidized but do not allow molybdenum to be oxidized. The heat treatment under these conditions makes it possible to selectively oxidize and remove only residual carbon contained in the molybdenum nitride (MoN) film 504, which is a surface layer. Note that the temperature for selective oxidation and the partial pressure ratio between the oxidizing atmosphere and the reducing atmosphere are not limited to the above-described ones and that any conditions may used as far as they are ones that allow carbon to be oxidized but do not allow molybdenum to be oxidized.

As shown in FIG. 7B, a part of the molybdenum nitride (MoN) film 504 in the region where the N-type MOSFET is to be formed is selectively removed (etched) using, e.g., a hydrogen peroxide solution. As shown in FIG. 7C, a molybdenum silicon nitride (MoSiN) film 505 having a work function of 4.2 eV is deposited on the entire surface to a thickness of 10 nm by, e.g., CVD.

As shown in FIG. 7D, a tungsten film 506 serving as a low-resistivity layer is deposited on the entire surface to a thickness of 80 nm by, e.g., CVD. After that, a silicon nitride film 507 is deposited on the entire surface to a thickness of 80 nm by, e.g., CVD.

As shown in FIG. 7E, resists (not shown) are selectively formed only in regions where gate electrodes of the N-type MOSFET and P-type MOSFET are to be formed. The silicon nitride film 507, tungsten film 506, molybdenum silicon nitride (MoSiN) film 505, and molybdenum nitride (MoN) film 504 are anisotropically etched using the resists as a mask. After that, ashing processing is performed to remove the resists. With the etching processing, gate electrodes 508n and 508p having a width of, e.g., 30 nm are formed.

As shown in FIG. 8A, a silicon nitride film 509 is deposited on the entire surface by, e.g., CVD, and then overall etchback is performed. With this process, a structure is formed in which the sidewalls of the gate electrodes 508n and 508p are surrounded by the silicon nitride film 509. Shallow diffusion layers 510 and 511 are formed on the two sides of the gate electrodes 508n and 508p in the silicon substrate 500. A specific method for forming the shallow diffusion layers 510 and 511 is the same as that in the second embodiment explained with reference to FIG. 6B.

A silicon nitride film 512 and a silicon oxide film 513 are deposited on the entire surface in this order by, e.g., CVD, and then overall etchback is performed. With this process, gate sidewall insulating films 514, each of which is composed of the silicon nitride film 512 and silicon oxide film 513, are formed to surround the silicon nitride films 509 formed on the sidewalls of the gate electrodes 508n and 508p, as. shown in FIG. 8B. Deep diffusion layers 515 and 516 are formed on the two sides of the gate electrodes 508n and 508p in the silicon substrate 500. A specific method for forming the deep diffusion layers 515 and 516 is the same as that in the second embodiment explained with reference to FIG. 6A.

In the above-described manner, source/drain diffusion layers 517 and 518 which are composed of the deep diffusion layer 515 and shallow diffusion layer 510 and the deep diffusion layer 516 and shallow diffusion layer 511, respectively, are formed on the two sides of the gate electrodes 508n and 508p in the silicon substrate 500. Nickel silicide layers 519 are formed on the surfaces of the source/drain diffusion layers 517 and 518. A specific method for forming the nickel silicide layer 519 is the same as that in the second embodiment explained with reference to FIG. 6C.

Finally, as shown in FIG. 8C, a first interlayer insulating film 520, contact plugs 521, a second interlayer insulating film 522, and wiring layers 523 are formed. A specific method for forming these components is the same as that in the second embodiment explained with reference to FIG. 6D. Note that the formation method in this embodiment is different from that in the second embodiment only in that when forming the contact plugs 521 on the upper surfaces of the gate electrodes 508n and 508p, the silicon nitride films 507 located at the outermost surfaces of the gate electrodes 508n and 508p are etched together with the first interlayer insulating film 520 such that the contact plugs 521 and tungsten films 506 are electrically connected. In this manner, a CMOS-type semiconductor device having the N-type MOSFET and P-type MOSFET is completed.

As described above, in this embodiment, the molybdenum nitride (MoN) film 504, which governs the threshold value of the gate electrode 508p of the P-type MOSFET, is subjected to selective oxidation processing under conditions that allow carbon to be oxidized but do not allow molybdenum to be oxidized. Accordingly, even if the thickness of each gate insulating film 503 changes, the flat band voltage can remain constant, the quality of the semiconductor device can be improved, and the cost for developing products can be suppressed.

Note that in this embodiment as well, each gate insulating film 503 need not be an oxide film containing hafnium, like the second embodiment. For example, an oxide of zirconium (Zr), titanium (Ti), tantalum (Ta), aluminum (Al), strontium (Sr), yttrium (Y), lanthanum (La), or the like or an oxide of a compound of any of the elements and silicon, such as ZrSiₓO_{y}, may be used. Alternatively, a film formed by stacking layers of these oxides may be used.

According to the above-described embodiments, there can be implemented a method for manufacturing a semiconductor device which can form a high-quality semiconductor device while suppressing variations in threshold value among P-type MOSFETs and can suppress the cost for developing products.

Having described the embodiments of the invention referring to the accompanying drawings, it should be understood that the present invention is not limited to those precise embodiments and various changes and modifications thereof could be made by one skilled in the art without departing from the spirit or scope of the invention as defined in the appended claims.

What is claimed is:

1. A method for manufacturing a semiconductor device, comprising:
forming a gate insulating film on a semiconductor substrate;
forming a conductor film constituting a gate electrode on the gate insulating film by a formation method using an organic material; and
heating the semiconductor substrate, on which the conductor film is formed, in a mixed atmosphere of an oxidizing atmosphere and a reducing atmosphere with a partial pressure ratio of the reducing atmosphere to the oxidizing atmosphere which is set such that carbon is oxidized and that a metal material constituting the conductor film is reduced.

2. The method for manufacturing the semiconductor device according to claim 1, wherein the metal material constituting the conductor film is one of a metal material having a work function of not less than 4.8 eV and less than 5.1 eV and an alloy of a plurality of metal materials each having a work function of not less than 4.8 eV and less than 5.1 eV.

3. The method for manufacturing the semiconductor device according to claim 1, wherein the metal material constituting the conductor film is one of a metal material belonging to Group VIa in a periodic table of elements and an alloy of a plurality of metal materials belonging to Group VIa in the periodic table of elements.

4. The method for manufacturing the semiconductor device according to claim 1, wherein the oxidizing atmosphere is a steam atmosphere, and the reducing atmosphere is a hydrogen atmosphere.

5. The method for manufacturing the semiconductor device according to claim 2, wherein the oxidizing atmosphere is a steam atmosphere, and the reducing atmosphere is a hydrogen atmosphere.

6. The method for manufacturing the semiconductor device according to claim 3, wherein the oxidizing atmosphere is a steam atmosphere, and the reducing atmosphere is a hydrogen atmosphere.

7. A method for manufacturing a semiconductor device in which a P-type MOS transistor is formed, comprising:
forming a gate insulating film on a semiconductor substrate;
forming a conductor film constituting a gate electrode of the P-type MOS transistor on the gate insulating film by a formation method using an organic material; and
heating the semiconductor substrate, on which the conductor film is formed, in a mixed atmosphere of an oxidizing atmosphere and a reducing atmosphere with a partial pressure ratio of the reducing atmosphere to the oxidizing atmosphere which is set such that carbon is oxidized and that a metal material constituting the conductor film is reduced.

8. The method for manufacturing the semiconductor device according to claim 7, wherein the metal material constituting the conductor film is one of a metal material having a work function of not less than 4.8 eV and less than 5.1 eV and an alloy of a plurality of metal materials each having a work function of not less than 4.8 eV and less than 5.1 eV.

9. The method for manufacturing the semiconductor device according to claim 7, wherein the metal material constituting the conductor film is one of a metal material belonging to Group VIa in a periodic table of elements and an alloy of a plurality of metal materials belonging to Group VIa in the periodic table of elements.

10. The method for manufacturing the semiconductor device according to claim 8, wherein the metal material constituting the conductor film is one of a metal material belonging to Group VIa in a periodic table of elements and an alloy of a plurality of metal materials belonging to Group VIa in the periodic table of elements.

11. The method for manufacturing the semiconductor device according to claim 7, wherein the oxidizing atmosphere is a steam atmosphere, and the reducing atmosphere is a hydrogen atmosphere.

12. The method for manufacturing the semiconductor device according to claim 8, wherein the oxidizing atmosphere is a steam atmosphere, and the reducing atmosphere is a hydrogen atmosphere.

13. The method for manufacturing the semiconductor device according to claim 9, wherein the oxidizing atmosphere is a steam atmosphere, and the reducing atmosphere is a hydrogen atmosphere.

14. A method for manufacturing a semiconductor device in which a P-type MOS transistor and an N-type MOS transistor are formed, comprising:
forming a gate insulating film on a semiconductor substrate;
forming a first conductor film constituting a gate electrode of the P-type MOS transistor on the gate insulating film by a formation method using an organic material;
heating the semiconductor substrate, on which the first conductor film is formed, in a mixed atmosphere of an oxidizing atmosphere and a reducing atmosphere with a partial pressure ratio of the reducing atmosphere to the oxidizing atmosphere which is set such that carbon is oxidized and that a metal material constituting the first conductor film is reduced;
removing a part of the first conductor film formed in a region where the N-type MOS transistor is to be formed; and
forming a second conductor film constituting a gate electrode of the N-type MOS transistor.

15. The method for manufacturing the semiconductor device according to claim 14, wherein the metal material constituting the first conductor film is one of a metal material having a work function of not less than 4.8 eV and less than 5.1 eV and an alloy of a plurality of metal materials each having a work function of not less than 4.8 eV and less than 5.1 eV.

16. The method for manufacturing the semiconductor device according to claim 14, wherein the metal material constituting the first conductor film is one of a metal material belonging to Group VIa in a periodic table of elements and an alloy of a plurality of metal materials belonging to Group VIa in the periodic table of elements.

17. The method for manufacturing the semiconductor device according to claim 15, wherein the metal material constituting the first conductor film is one of a metal material belonging to Group VIa in a periodic table of elements and an alloy of a plurality of metal materials belonging to Group VIa in the periodic table of elements.

18. The method for manufacturing the semiconductor device according to claim 14, wherein the oxidizing atmosphere is a steam atmosphere, and the reducing atmosphere is a hydrogen atmosphere.

19. The method for manufacturing the semiconductor device according to claim 15, wherein the oxidizing atmosphere is a steam atmosphere, and the reducing atmosphere is a hydrogen atmosphere.

20. The method for manufacturing the semiconductor device according to claim 16, wherein the oxidizing atmosphere is a steam atmosphere, and the reducing atmosphere is a hydrogen atmosphere.
